(19) United States
(12) Patent Application Publication
(10) Pub. No.: US 2025/0241145 A1
(43) Pub. Date: Jul. 24, 2025

(54) DISPLAY APPARATUS

(71) Applicant: LG Display Co., Ltd., Seoul (KR)

(72) Inventors: JunYoung KWON, Goyang-si (KR); Yein HONG, Goyang-si (KR)

(21) Appl. No.: 18/905,734

(22) Filed: Oct. 3, 2024

(30) Foreign Application Priority Data
Jan. 23, 2024 (KR) 10-2024-0010084

(51) Int. Cl. H10K 59/131; H10K 59/80

(52) U.S. Cl. CPC H10K 59/131; H10K 59/873

(57) ABSTRACT

A display apparatus includes a substrate configured by an active area and a non-active area including a first area adjacent to the active area, a second area adjacent to the first area, and a third area adjacent to the second area. The display apparatus further includes a first signal line and a second signal line disposed in the non-active area. The first signal line and the second signal line include a first part and a second part which are disposed to have different angles, respectively. A location where an angle between the first part and the second part is changed is located in the second area.

### CROSS-REFERENCE TO RELATED APPLICATIONS

This application claims the priority of Korean Patent Application No. 10-2024-0010084 filed on Jan. 23, 2024, in the Korean Intellectual Property Office, the disclosure of which is incorporated herein by reference.

### BACKGROUND

### Technical Field

The present disclosure relates to a display apparatus, and more particularly, to a display apparatus having a structure which suppresses moisture permeation from the outside.

### Description of the Related Art

A recent display apparatus which is capable of displaying various information and interacting with a user who watches the information is required to have various sizes, various shapes, and various functions.

Examples of the display apparatus include a liquid crystal display apparatus (LCD), an electrophoretic display apparatus (FPD), a light emitting diode display apparatus (LED), and the like.

As the display apparatus is utilized for various purposes, in order to provide more various functions to users, optical components, such as a camera, are provided together. In order to add optical components, such as a camera, a display apparatus in which a part of the display apparatus is cut or a hole is formed to dispose optical components has been developed.

External moisture or oxygen may flow into an active area through a wiring line disposed in a non-active area of the substrate. Moisture or oxygen permeating into the active area interrupts image operation of the active area to cause abnormal image display problems.

Accordingly, various studies are being conducted to block moisture or oxygen which flows into the non-active area of the display apparatus from permeating into the active area, but are still insufficient so that development thereof is urgently needed.

### BRIEF SUMMARY

An object to be achieved by the present disclosure is to provide a display apparatus in which a location where angles of a first signal line and a second signal line disposed in a non-active area are changed is disposed in an area of the non-active area from which a planarization layer is removed. By doing this, permeation of external moisture or oxygen into the display apparatus through the non-active area may be suppressed.

Another object to be achieved by the present disclosure is to provide a display apparatus with an improved reliability in which permeation of external moisture or oxygen into the display apparatus through the non-active area is blocked to normally transmit a signal.

Objects of the present disclosure are not limited to the above-mentioned objects, and other objects, which are not mentioned above, can be clearly understood by those skilled in the art from the following descriptions.

According to an aspect of the present disclosure, a display apparatus includes a substrate which is configured by an active area and a non-active area including a first area adjacent to the active area, a second area adjacent to the first area, and a third area adjacent to the second area; and a first signal line and a second signal line disposed in the non-active area. Further, the first signal line and the second signal line include a first part and a second part which are disposed to have different angles and a location where an angle is changed may be located in the second area.

According to the exemplary embodiment of the present disclosure, in the display apparatus, a location where angles of a first signal line and a second signal line disposed in a non-active area are changed is disposed in an area of the non-active area from which a planarization layer is removed. Therefore, moisture or oxygen which flows into the non-active area may be suppressed from moving to the active area.

Other detailed matters of the exemplary embodiments are included in the detailed description and the drawings.

According to the exemplary embodiment of the present disclosure, in the display apparatus, a location where angles of a first signal line and a second signal line disposed in a non-active area are changed overlaps a first power line. Therefore, moisture or oxygen which flows into the non-active area may be blocked from moving to the active area.

According to the exemplary embodiment of the present disclosure, in the display apparatus, moisture or oxygen permeating into the active area is suppressed to ensure a stability of a thin film transistor during the operation to improve a display quality.

The effects of the present disclosure are not limited to the aforementioned effects, and other effects, which are not mentioned above, will be apparently understood to a person having ordinary skill in the art from the following description.

### BRIEF DESCRIPTION OF THE SEVERAL VIEWS OF THE DRAWINGS

The above and other aspects, features and other advantages of the present disclosure will be more clearly understood from the following detailed description taken in conjunction with the accompanying drawings, in which:

FIG. 1 is a display apparatus according to exemplary embodiments of the present disclosure;

FIG. 2 is a plan view of a display apparatus according to an exemplary embodiment of the present disclosure;

FIG. 3 is a plan view enlarging an area A of FIG. 2 according to an exemplary embodiment of the present disclosure;

FIG. 4 is a cross-sectional view of an active area (I-I′) according to an exemplary embodiment of the present disclosure; and

FIG. 5 is a cross-sectional view of II-II′ of FIG. 3 according to an exemplary embodiment of the present disclosure.

### DETAILED DESCRIPTION

Advantages and characteristics of the present disclosure and a method of achieving the advantages and characteristics will be clear by referring to exemplary embodiments described below in detail together with the accompanying drawings. However, the present disclosure is not limited to the exemplary embodiments disclosed herein but will be implemented in various forms. The exemplary embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the exemplary embodiments of the present disclosure are merely examples, and the present disclosure is not limited thereto. Like reference numerals generally denote like elements throughout the specification. Further, in the following description of the present disclosure, a detailed explanation of known related technologies may be omitted to avoid unnecessarily obscuring the subject matter of the present disclosure. The terms such as “including,” “having,” and “consist of” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on,” “above,” “below,” and “next”, one or more parts may be positioned between the two parts unless the terms are used with the term “immediately” or “directly” is not used.

When the relation of a time sequential order is described using the terms such as “after,” “continuously to,” “next to,” and “before,” the order may not be continuous unless the terms are used with the term “immediately” or “directly.”

Although the terms “first,” “second,” and the like are used for describing various components, these components are not confined by these terms. These terms are merely used for distinguishing one component from the other components. Therefore, a first component to be mentioned below may be a second component in a technical concept of the present disclosure.

In describing components of the exemplary embodiment of the present disclosure, terminologies such as first, second, A, B, (a), (b), and the like may be used. These terminologies are used to distinguish a component from the other component, but a nature, an order, or the number of the components is not limited by the terminology. When a component is “linked,” “coupled,” or “connected” to another component, the component may be directly linked or connected to the other component. However, unless specifically stated otherwise, it should be understood that a third component may be interposed between the components which may be indirectly linked or connected.

It should be understood that “at least one” includes all combinations of one or more of associated components. For example, “at least one of first, second, and third components” means that not only a first, second, or third component, but also all combinations of two or more of first, second, and third components are included.

In the present specification, a “display apparatus” may include a display apparatus which includes a display panel and a driver for driving the display panel, in a narrow sense, such as a liquid crystal module (LCM), an organic light emitting module (OLED module), and a quantum dot module. Further, the “display apparatus” may further include a set electronic apparatus or a set apparatus (or a set device) which is a complete product or a final product including an LCM, an OLED module, a QD module, etc., such as a notebook computer, a television, or a computer monitor, an automotive display apparatus or equipment display apparatus including another type of vehicle and a mobile electronic apparatus including a smart phone or an electronic pad.

Accordingly, the display apparatus of the present disclosure may include not only a display apparatus itself in a narrow sense such as an LCM, an OLED module, a QD module, etc., but also an applied product or a set apparatus which is a final consumer device including the LCD, the OLED module, the QD module, etc.

Further, in some cases, the LCM or the OLED module which is configured by a display panel and a driver may be represented as “a display apparatus” and an electronic device as a complete product including the LCM and the OLED module may be represented as a “set apparatus”. For example, the display apparatus in the narrow sense includes a liquid crystal (LCD) display panel, an OLED display panel, or a quantum dot display panel and a source PCB which is a controller for driving the display panel. In contrast, the set apparatus may be a concept further including a set PCB which is a set controller which is electrically connected to the source PCB to control the entire set apparatus.

As a display panel used in the exemplary embodiment of the present disclosure, any type of display panel such as a liquid crystal display panel, an organic light emitting diode (OLED) display panel, and an electroluminescent display panel may be used. Further, a display panel used for the display apparatus according to the exemplary embodiment of the present disclosure is not limited to a shape or a size of the display panel.

The features of various exemplary embodiments of the present disclosure can be partially or entirely coupled to or combined with each other and can be interlocked and operated in technically various ways, and the exemplary embodiments can be carried out independently of or in association with each other.

Hereinafter, the exemplary embodiment of the present disclosure will be described with reference to the accompanying drawings and exemplary embodiments as follows. Scales of components illustrated in the accompanying drawings are different from the real scales for the purpose of description, so that the scales are not limited to those illustrated in the drawings.

Hereinafter, an exemplary embodiment of the present disclosure will be described in detail with reference to the drawings.

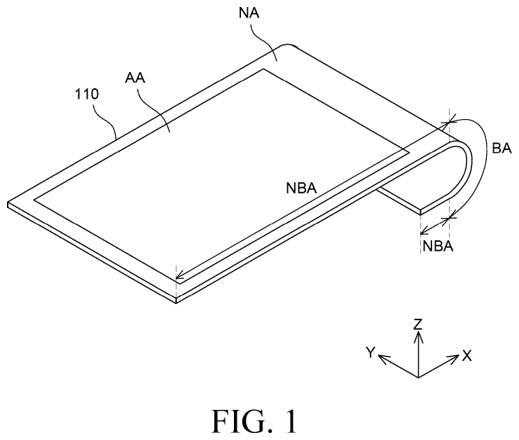

FIG. 1 is a display apparatus according to exemplary embodiments of the present disclosure.

Referring to FIG. 1, a substrate 110 may include a bending area BA and a non-bending area NBA. The non-bending area NBA may include two or more areas according to an area of the substrate 110. For example, the substrate 110 has one bending area BA between two non-bending areas NBA.

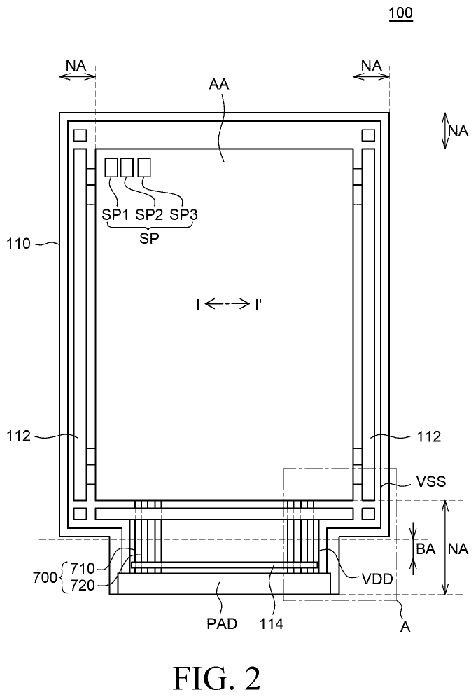

The bending area BA is an area formed by bending a part of the substrate 110. For example, the bending area BA is an area in which a part of the substrate 110 is bent to dispose the pad unit PAD (FIG. 2) and an external module bonded to the pad unit PAD on a rear surface of the substrate 110. For example, as the bending area BA is bent toward a rear surface of the substrate 110, the external module bonded to the pad unit PAD of the substrate 110 moves toward the rear surface of the substrate 110 so that the external module is not visible as seen from the top of the substrate 110. Further, as the bending area BA is bent, the size of the non-active area NA visible from the top of the substrate 110 is reduced so that a narrow bezel may be implemented.

The non-bending area NBA is an area in which a part of the substrate 110 is flat without being bent. Non-bending areas NBA having two areas may face each other.

A plurality of pixels may be disposed in a part of the non-bending area NBA. For example, the plurality of pixels may be disposed in the active area AA disposed in the non-bending area NBA.

FIG. 2 is a plan view of a display apparatus according to an exemplary embodiment of the present disclosure.

Referring to FIG. 2, the substrate 110 may include an active area AA (or a display area) and a non-active area NA (or non-display area) which encloses the active area AA. The non-active area NA of the substrate 110 is adjacent to the active area AA and may be disposed at the outside from the active area AA.

The active area AA is an area where pixels are disposed to display images.

The pixel disposed in the active area AA may further include a plurality of sub pixels SP1, SP2, and SP3. The plurality of sub pixels SP1, SP2, and SP3 is individual units which emit light and may emit red, green, blue, and/or white light and the exemplary embodiments of the present disclosure are not limited thereto.

The active area AA may include an organic light emitting diode. Each of the plurality of sub pixels SP1, SP2, and SP3 may include an emitting element layer for displaying images and a thin film transistor for driving the emitting element layer.

One sub pixel SP may include a plurality of transistors, a capacitor and a plurality of wiring lines. For example, one sub pixel SP may be configured with a structure 2T1C including two transistors and one capacitor, but is not limited thereto. Also, one sub pixel SP may be configured with 3T1C, 4T1C, 5T1C, 6T1C, 7T1C, 3T2C, 4T2C, 5T2C, 6T2C, 7T2C, and 8T2C, and may be implemented according to a structure and a type of thin film transistor.

The non-active area NA may be disposed in the vicinity of the active area AA. For example, the non-active area NA may be an area which encloses the active area AA. The non-active area NA may be an area extending from the active area AA. Alternatively, the non-active area NA may be an area in which a plurality of sub pixels SP1, SP2, and SP3 is not disposed, but is not limited thereto.

Even though in FIG. 2, it is illustrated that the non-active area NA encloses a quadrangular active area AA, a shape of the active area AA and a shape and placement of the non-active area NA adjacent to the active area AA are not limited to the example illustrated in FIG. 2. The active area AA and the non-active area NA may have shapes suitable for a design of an electronic device including the display apparatus 100. In the case of a display apparatus which is wearable by a user may have a circular shape such as a watch and the concepts of the exemplary embodiments of the present disclosure may also be applied to a free-form display apparatus which is applicable to a vehicle dash board. An exemplary shape of the active area AA may be a pentagon, a hexagon, a circle, or an oval, but is not limited thereto.

The non-active area NA is an area where various wiring lines and driving circuits for driving the plurality of sub pixels SP1, SP2, and SP3 disposed in the active area AA are disposed. For example, in the non-active area NA, various ICs such as a gate driver and a data driver and driving circuits may be disposed. The non-active area NA may be a bezel area, but is not limited to the term.

The display apparatus 100 of the present disclosure may include various additional elements to generate various signals or drive a plurality of sub pixels SP1, SP2, and SP3 in an active area AA. For example, the driving circuit for controlling (or driving) the plurality of sub pixels SP1, SP2, and SP3 may include a gate driver, a driver IC, a signal line, a multiplexer (MUX), an electrostatic discharge (ESD) circuit, a power line, an inverter circuit, a connection line, and the like. The display apparatus 100 may include additional elements other than a function for driving the plurality of sub pixels SP1, SP2, and SP3. For example, the display apparatus 100 may include additional elements which provide a touch sensing function, a user authentication function (for example, fingerprint recognition), a multilevel pressure sensing function, or a tactile feedback function and the exemplary embodiments of the present disclosure are not limited thereto. The mentioned additional elements may be located in the non-active area NA or an external circuit connected to a connection interface and the exemplary embodiments of the present disclosure are not limited thereto.

The pad unit PAD may be disposed at one side of the non-active area NA. The pad unit PAD may transmit a driving signal or transmit or receive a touch signal with an external power and may be electrically connected to an external module, such as a flexible printed circuit board (FPCB) or a chip on film (COF), and may be a metal pattern bonded to the FPCB and the COF. Even though it is illustrated that the pad unit PAD is disposed at one side of the substrate 110, a shape and a placement of the pad unit PAD are not limited thereto.

The driver IC 114 may be disposed at one side of the non-active area NA. For example, the driver IC 114 is adjacent to the pad unit PAD and may be disposed inside more than the pad unit PAD. The driver IC 114 may include various driving circuits, such as a data voltage and/or an emission signal of a light emitting diode.

The pad unit PAD, the driver IC 114, and the FPCB which is electrically connected to the pad unit PAD move to the rear surface of the substrate 110 as the substrate 110 is bent and are not visible as seen from the top of the substrate 110. Further, as the bending area BA is bent, the size of the non-active area NA visible from the top of the substrate 110 is reduced so that a narrow bezel may be implemented.

The gate driver 112 may be disposed at another side and the other side opposite to another side of the non-active area NA. The gate driver 112 may supply a gate signal to the thin film transistor. The gate driver 112 includes various gate driving circuits and the gate driving circuits may be directly formed on the substrate 110. In this case, the gate driver 112 may be a gate-in-panel (GIP), but is not limited by the term.

The gate driver 112 may be disposed between the active area AA and the dam. A first power line VDD, a second power line VSS, the multiplexer (MUX), the electrostatic discharge (ESD) circuit unit, and the signal line 700 may be disposed between the active area AA and the pad unit PAD of the non-active area NA. The exemplary embodiments of the present disclosure are not limited thereto.

The first power line VDD, the second power line VSS, the multiplexer (MUX), and the signal line 700 may be disposed between the active area AA and the bending area BA, but are not limited thereto. For example, the first power line VDD, the second power line VSS, the multiplexer (MUX), and the signal line 700 may extend to a non-bending area adjacent to the active area AA. Further, the first power line VDD, the second power line VSS, the multiplexer (MUX), and the signal line 700 may extend to a non-bending area adjacent to the pad unit PAD of the non-active area NA.

The signal line 700 may include a first signal line 710 and a second signal line 720. The first signal line 710 and the second signal line 720 may be disposed in a part of the non-active area NA. The first signal line 710 and the second signal line 720 may also be disposed between the active area AA and the bending area BA of the display apparatus.

The signal line 700 may be a component which transmits a signal (for example, a voltage) from the external module bonded to the pad unit PAD to the active area AA or a circuit unit such as the gate driver 112. For example, various signals, such as various gate signals or data signals, and voltages may be transmitted through the signal line 700. For example, the first signal line 710 may transmit a gate signal supplied from the external module to the active area AA and may be connected to the scan line, but is not limited thereto.

The second signal line 720 may transmit a data signal supplied from the external module to the active area AA, but is not limited thereto. The second signal line 720 may be connected to a data line, but is not limited thereto.

The first power line VDD may be a high potential voltage line. For example, the first power line VDD may be disposed to overlap the first signal line 710, the second signal line 720, and the dam 900. The first signal line 710 and the second signal line 720 may be disposed diagonally to the first power line VDD in an area in which the first signal line 710 and the second signal line 720 overlap the first power line VDD.

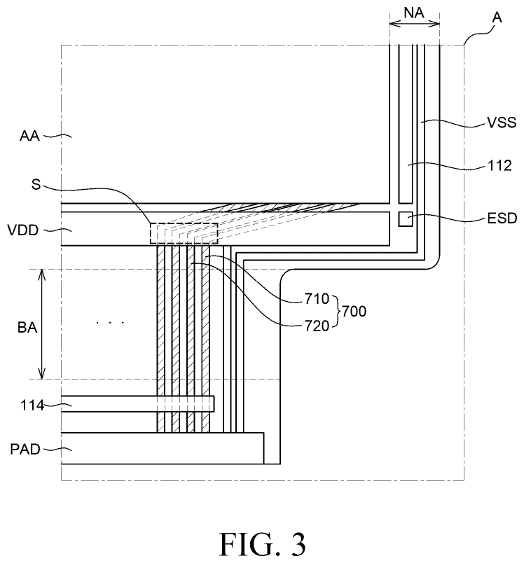

The placement of the first power line VDD and the first signal line 710 and the second signal line 720 will be described below with reference to FIG. 3 which is an enlarged view of the area “A” of FIG. 2.

The second power line VSS may be a low potential voltage line. The second power line VSS may be disposed to enclose at least a part of the active area AA.

The dam may be disposed in the non-active area NA so as to enclose all or a part of the active area AA. The dam is adjacent to the active area AA and may be disposed at the outside from the active area AA.

The dam may be disposed along the periphery of the active area AA to control the flow of a layer including an organic material of the encapsulation unit disposed on the light emitting element layer. The number of dams may be one or plural and the exemplary embodiments of the present disclosure are not limited thereto.

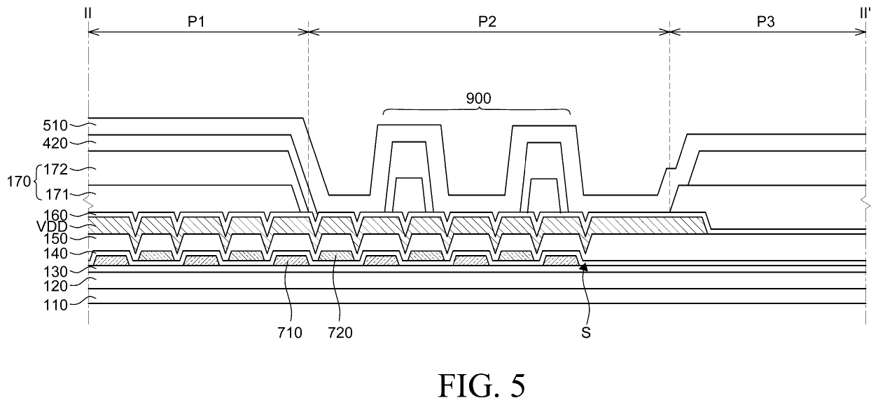

The dam will be described in FIG. 5.

A panel crack detector may be further disposed in a part of the non-active area NA of the substrate 110.

The panel crack detector may be disposed between an end point (or an end) of the substrate 110 and the dam or may be disposed below the dam and may overlap at least a part of the dam.

The panel crack detector is disposed at the outer periphery of the display apparatus 100 and may detect the defect, such as a crack which may be generated at the outer periphery of the display apparatus 100.

A hole may be further included in the active area AA. The hole may be located between the plurality of sub pixels SP1, SP2, and SP2 disposed in the active area AA. The hole may be an area in which an optical component, such as a camera or an optical sensor is disposed. The optical sensor may include a proximity sensor, an infrared sensor, an ultraviolet sensor, and the like, but the exemplary embodiments of the present disclosure are not limited thereto. The display apparatus 100 may ensure a space in which an optical component is disposed, by a hole which passes through a partial configuration of the display apparatus 100.

A crack stopper structure may be further disposed in a part of the non-active area NA of the substrate 110. The crack stopper structure may be disposed to be adjacent to the outermost end of the substrate 110.

The crack stopper structure may suppress a crack caused by the external shock from being transmitted into the display apparatus 100. For example, the crack stopper structure may suppress a shock generated from a trimming line of the substrate 110 during a cutting process from reaching the gate driver 112, the electrostatic discharge (ESD) circuit, or the second power line VSS formed in the non-active area NA to cause a crack. Further, the crack topper structure may suppress a dark spot and pixel shrinkage generated by providing a moisture permeation path to a light emitting element layer or a thin film transistor formed in the active area AA.

The crack stopper structure may be formed of an inorganic material or an organic material and may be formed with a multi-layered structure of inorganic material/organic material.

FIG. 3 is a plan view enlarging an area “A” of FIG. 2 according to an exemplary embodiment of the present disclosure.

Referring to FIG. 3, the first signal line 710 and the second signal line 720 may include a first part and a second part having different angles, respectively. For example, the first part may be a part perpendicular to the active area AA and may have a long vertical straight line shape as seen from a plan view. The second part may be a part having a different angle from the first part and may have a diagonal shape as seen from a plan view. The first signal line 710 and the second signal line 720 may include a second part which connects from the pad unit PAD or the drive IC 114 to each sub pixel SP (FIG. 2) disposed in the active area AA to connect the sub pixel SP disposed at the outer periphery of the active area AA.

A location S where an angle between the first signal line 710 and the second signal line 720 is changed may overlap the power line. For example, the location S where an angle between the first signal line 710 and the second signal line 720 is changed may overlap the first power line VDD. Further, for example, the location S where an angle between the first signal line 710 and the second signal line 720 is changed is parts in which the first part and the second part of each of the first signal line 710 and the second signal line 720 are connected and positions may be different to suppress the overlapping between the first signal line 710 and the second signal line 720.

Details will be described below in detail together with the cross section in FIG. 5.

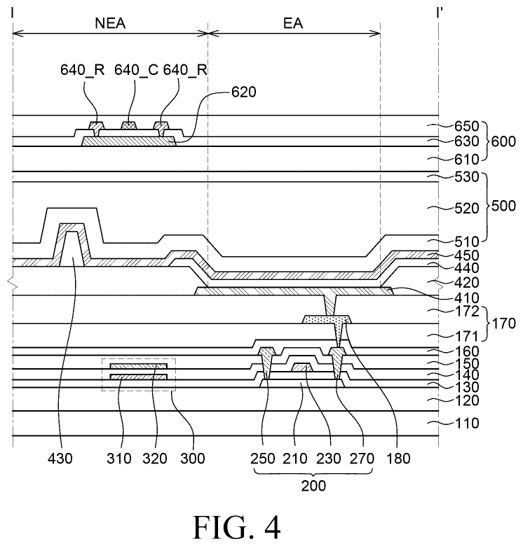

Hereinafter, a display apparatus of the present disclosure will be described in detail with reference to FIGS. 4 and 5.

FIG. 4 is a cross-sectional view of an active area of a display apparatus according to another exemplary embodiment of the present disclosure. For example, FIG. 4 illustrate an example of a cross-sectional structure of an area I-I′ illustrated in FIG. 2.

FIG. 5 is a cross-sectional view of a non-active area of a display apparatus according to another exemplary embodiment of the present disclosure. For example, FIG. 5 illustrates an example of a cross-sectional structure of an area II-II′ illustrated in FIG. 3.

Referring to FIGS. 4 and 5, the substrate 110 may support various components of the display apparatus. The substrate 110 may be formed of a glass or a plastic material having flexibility.

For example, the substrate 110 may be formed of at least one of polyimide (PI), polymethylmethacrylate (PMMA), polyethylene terephthalate (PET), polyethersulfone, and polycarbonate, but is not limited thereto.

When the substrate 110 is formed of polyimide, the substrate is configured by two polyimide layers. Further, an inorganic film may be further disposed between two polyimide layers.

The substrate 110 may be referred to as a concept including an element and a functional layer formed on the substrate 110, for example, a switching thin film transistor, a driving thin film transistor connected to the switching thin film transistor, an organic light emitting diode connected to the driving thin film transistor, and a protection layer. However, it is not limited thereto.

A buffer layer 120 may be disposed on the entire surface of the substrate 110.

The buffer layer 120 is formed on the substrate 110 to block a material in the substrate 110 from moving to the thin film transistor or the semiconductor layer during a deposition process.

The buffer layer 120 may be formed of an insulating inorganic material such as silicon nitride (SiNx) or silicon oxide (SiOx) and also may be formed of other insulating organic material, but is not limited thereto.

The buffer layer 120 may be formed as a single layer of silicon nitride (SiNx) or silicon oxide (SiOx) or a plurality of layers thereof. When the buffer layer 120 is formed as a plurality of layers, silicon oxide (SiOx) and silicon nitride (SiNx) are alternately formed, but the exemplary embodiments of the present disclosure are not limited thereto. The buffer layer 120 may be omitted according to a type or a material of the substrate 110 and a structure and a type of the thin film transistor.

The thin film transistor 200 may be disposed on the buffer layer 120. The thin film transistor 200 may include a semiconductor pattern, a gate electrode, a source electrode, and a drain electrode.

For the convenience of description, only one thin film transistor 200, among various thin film transistors, is illustrated, but another thin film transistor is also included in the display apparatus 100. Further, for the convenience of description, the thin film transistor is illustrated as a top gate structure in which a gate electrode which configures the thin film transistor is located above the semiconductor layer, but it is not limited to this structure. Therefore, the thin film transistor is also implemented as another structure, such as a bottom gate structure in which the gate electrode is disposed below the semiconductor layer or a double gate structure in which gate electrodes are disposed above and below the semiconductor layer.

A semiconductor pattern 210 of the thin film transistor 200 may be disposed on the buffer layer 120.

The semiconductor pattern 210 may be formed of a polycrystalline semiconductor. For example, the polycrystalline semiconductor may be formed of a low temperature poly silicon (LTPS) having a high mobility, but is not limited thereto. When the semiconductor pattern is formed of a polycrystalline semiconductor, the energy consumption power is low and the reliability is excellent.

Further, the semiconductor pattern 210 may be formed of an oxide semiconductor. For example, the semiconductor pattern may be formed of any one of indium gallium zinc oxide (IGZO), indium zinc oxide (IZO), indium gallium tin oxide (IGTO), and indium gallium oxide (IGO), but is not limited thereto. When the semiconductor pattern 210 is formed of an oxide semiconductor, it has an excellent effect to block the leakage current so that the luminance variation of the sub pixel during the low speed driving may be minimized.

When the semiconductor pattern 210 is formed of the polycrystalline semiconductor or the oxide semiconductor, a conductive area may be included in a partial area of the semiconductor pattern 210.

The semiconductor pattern 210 may be made of amorphous silicon (a-Si) or various organic semiconductor materials such as pentacene, but is not limited thereto.

A first insulating layer 130 may be disposed on the entire area of the substrate 110 on the semiconductor pattern 210.

The first insulating layer 130 is disposed between the semiconductor pattern 210 and the gate electrode 230 to insulate the semiconductor pattern 210 and the gate electrode 230 from each other.

The first insulating layer 130 may be formed of an insulating inorganic material such as silicon nitride (SiNx) or silicon oxide (SiOx) or other insulating organic material, but is not limited thereto.

The first insulating layer 130 may include a hole to electrically connect a source electrode 250 and a drain electrode 270 to the semiconductor pattern 210.

The gate electrode 230 of the thin film transistor 200 may be disposed on the first insulating layer 130. The gate electrode 230 may be disposed so as to overlap the semiconductor pattern 210.

A storage capacitor 300 may be disposed on the first insulating layer 130. The storage capacitor 300 may include a first capacitor electrode 310 and a second capacitor electrode 320. The storage capacitor 300 stores a data voltage applied through a data line for a predetermined period to supply the data voltage to the first electrode 410.

The first capacitor electrode 310 of the storage capacitor 300 may be disposed on the first insulating layer 130.

A plurality of first signal lines 710 may be disposed on the first insulating layer 130 of the non-active area NA. The plurality of first signal lines 710 may be disposed to be spaced apart from each other.

The gate electrode 230, the first capacitor electrode 310, and the first signal line 710 may be disposed on the same layer. For example, the gate electrode 230, the first capacitor electrode 310, and the first signal line 710 may be disposed on the first insulating layer 130.

The gate electrode 230, the first capacitor electrode 310, and the first signal line 710 may be formed by the same process or the same material.

The gate electrode 230, the first capacitor electrode 310, and the first signal line 710 may be formed as a single layer or a plurality of layers formed of any one of molybdenum (Mo), copper (Cu), titanium (Ti), aluminum (Al), chrome (Cr), gold (Au), nickel (Ni), neodymium (Nd), tungsten (W), gold (Au), and transparent conductive oxide (TCO), or an alloy thereof, but are not limited thereto.

A second insulating layer 140 may be disposed in the entire area of the substrate 110 on the gate electrode 230, the first capacitor electrode 310, and the first signal line 710.

The second insulating layer 140 is disposed between the gate electrode 230 and the source electrode 250 and the drain electrode 270 to insulate the gate electrode 230 from the source electrode 250 and the drain electrode 270.

The second insulating layer 140 may include a hole to electrically connect a source electrode 250 and a drain electrode 270 to the semiconductor pattern 210.

The second insulating layer 140 may be formed of an insulating inorganic material such as silicon nitride (SiNx) or silicon oxide (SiOx) or other insulating organic material, but is not limited thereto.

The second capacitor electrode 320 of the storage capacitor 300 may be disposed on the second insulating layer 140.

The second capacitor electrode 320 may be disposed so as to overlap the first capacitor electrode 310.

A plurality of second signal lines 720 may be disposed on the second insulating layer 140 of the non-active area NA. The plurality of second signal lines 720 may be disposed to be spaced apart from each other.

The second signal line 720 may be alternately disposed with the first signal line 710 disposed therebelow without at least partially overlapping.

The second capacitor electrode 320 and the second signal line 720 may be disposed on the same layer. For example, the second capacitor electrode 320 and the second signal line 720 may be disposed on the second insulating layer 140.

The second capacitor electrode 320 and the second signal line 720 may be formed by the same process or the same material.

The second capacitor electrode 320 and the second signal line 720 may be formed as a single layer or a plurality of layers formed of any one of molybdenum (Mo), copper (Cu), titanium (Ti), aluminum (Al), chrome (Cr), gold (Au), nickel (Ni), neodymium (Nd), tungsten (W), gold (Au), and transparent conductive oxide (TCO), or an alloy thereof, but are not limited thereto.

A third insulating layer 150 may be disposed in the entire area of the substrate 110 on the second capacitor electrode 320 and the second signal line 720.

The third insulating layer 150 is disposed between the gate electrode 230 and the source electrode 250 and the drain electrode 270 to insulate the gate electrode 230 from the source electrode 250 and the drain electrode 270.

The third insulating layer 150 may be formed of an insulating inorganic material, such as silicon nitride (SiNx) or silicon oxide (SiOx) or may be formed of other insulating organic material, but is not limited thereto.

The third insulating layer 150 may include a hole to electrically connect the source electrode 250 and the drain electrode 270 to the semiconductor pattern 210.

The source electrode 250 and the drain electrode 270 may be disposed on the third insulating layer 150.

Each of the source electrode 250 and the drain electrode 270 may be electrically connected to the semiconductor pattern 210 through the holes of the first insulating layer 130, the second insulating layer 140, and the third insulating layer 150.

The first power line VDD may be disposed on the third insulating layer 150 of the non-active area NA. The first power line VDD may be disposed between the active area AA and the bending area BA of the non-active area.

The source electrode 250, the drain electrode 270, and the first power line VDD may be disposed on the same layer. For example, the source electrode 250, the drain electrode 270, and the first power line VDD may be disposed on the third insulating layer 150.

The source electrode 250, the drain electrode 270, and the first power line VDD may be formed by the same process.

A second power line VSS (FIG. 3) may be further disposed on the third insulating layer 150. The second power line VSS may supply a low potential voltage.

The source electrode 250, the drain electrode 270, and the first power line VDD may be formed as a single layer or a plurality of layers formed of any one of molybdenum (Mo), copper (Cu), titanium (Ti), aluminum (Al), chrome (Cr), gold (Au), nickel (Ni), neodymium (Nd), tungsten (W), gold (Au), and transparent conductive oxide (TCO), or an alloy thereof, but are not limited thereto. For example, the source electrode 250, the drain electrode 270, and the first power line VDD may be formed with a triple layered structure of titanium (Ti)/aluminum (Al)/titanium (Ti) formed of a conductive metal material, but are not limited thereto.

A protection layer 160 may be disposed in the entire area of the substrate 110 on the source electrode 250, the drain electrode 270, and the first power line VDD.

The protection layer 160 may protect the thin film transistor 200. The protection layer 160 may be formed of an insulating inorganic material such as silicon nitride (SiNx) or silicon oxide (SiOx) or may also be formed of other insulating organic material, but is not limited thereto.

The protection layer 160 may include a hole to electrically connect the thin film transistor 200 to the first electrode 410.

The protection layer 160 may cover the first power line VDD disposed in the non-active area NA. For example, the protection layer 160 may be disposed to cover a top surface and a side surface of the first power line VDD.

The protection layer 160 may be omitted according to a structure and a type of the thin film transistor.

A planarization layer 170 may be disposed on the protection layer 160.

The planarization layer 170 protects the thin film transistor 200 disposed below the planarization layer 170 and may relieve or planarize a step due to various patterns.

The planarization layer 170 may be disposed as a single layer, but may be disposed as two or more layers in consideration of the placement of the electrode.

As the display apparatus 100 is developed to a higher resolution, various signal lines increase, so that it is difficult to place all wiring lines on one layer while ensuring the minimum interval. Therefore, additional layers may be configured. There is a margin in the placement of the wiring line by providing such an additional layer, which makes it easier to design the electric wire/electrode placement. Further, when a dielectric material is used for the planarization layer 170 configured as a plurality of layers, the planarization layer 170 may be utilized to form a capacitance between metal layers.

When two planarization layers 170 are provided, the planarization layers may include a first planarization layer 171 and a second planarization layer 172.

The first planarization layer 171 and the second planarization layer 172 may be formed of at least one or more materials of organic insulating materials, such as benzocyclobutene (BCB), acrylic resin, epoxy resin, phenolic resin, polyamide resin, or polyimide resin, but are not limited thereto.

When the planarization layer 170 is configured as two layers, a hole is formed in the first planarization layer 171 and a connection electrode 180 may be disposed in the hole. The second planarization layer 172 having a hole may be disposed on the first planarization layer 171 and the connection electrode 180. The first electrode 410 may be disposed in the hole of the second planarization layer 172. Therefore, the thin film transistor 200 and the first electrode 410 may be electrically connected through the connection electrode 180.

For example, the connection electrode 180 may be disposed on the first planarization layer 171. One end (or a part) of the connection electrode 180 is connected to the thin film transistor 200 and the other end (or the other part) of the connection electrode 180 is connected to the first electrode 410.

The connection electrode 180 may be formed as a single layer or a plurality of layers formed of any one of molybdenum (Mo), copper (Cu), titanium (Ti), aluminum (Al), chrome (Cr), gold (Au), nickel (Ni), neodymium (Nd), tungsten (W), gold (Au), and transparent conductive oxide (TCO), or an alloy thereof, but is not limited thereto.

The connection electrode 180 may be omitted depending on the structure and the type of the display apparatus.

The planarization layer 170 may be disposed in a first area P1 and a third area P3 of the non-active area and an end point of the planarization layer 170 may divide the first area P1 and the second area P2. For example, the first area P1 may be an area from an end point of the active area AA to an end point of the planarization layer 170 and the second area P2 may be an area in which the planarization layer 170 is not disposed.

The planarization layer 170 may be disposed in the active area AA and the non-active area NA and may be partially etched. A dam 900 may be disposed in the second area P2 in which the planarization layer 170 is etched in the non-active area NA. For example, the dam 900 is disposed in the second area P2 in which the planarization layer 170 is etched to suppress overflowing of the second encapsulation layer 520 which is formed of an organic material during a processing process before being cured. The dam 900 may include at least one or more or a plurality of patterns.

The dam 900 may be disposed around the active area AA along the active area AA or may be disposed around the first area P1 along the first area P1 of the non-active area NA of FIG. 5. The dam 900 may be disposed between the first area P1 and the third area P3 or the bending area BA.

The dam 900 may be disposed as a plurality of layers using at least one or more materials. For example, when the dam 900 is formed as a plurality of layers, the dam may be formed of the same material as at least one of the second planarization layer 172 and the bank 420 and may be formed together when the second planarization layer 172 and the bank 420 are formed, but is not limited thereto.

The first electrode 410 may be disposed on the planarization layer 170. The first electrode 410 may be an anode electrode.

When the display apparatus 100 is a top emission type, the first electrode 410 may be disposed using an opaque conductive material as a reflective electrode which reflects light. The first electrode 410 may be formed of at least one or more of silver (Ag), aluminum (Al), gold (Au), molybdenum (Mo), tungsten (W), chrome (Cr), or an alloy thereof. For example, the first electrode 410 may be formed with a triple layered structure of silver (Ag)/lead (Pb)/copper (Cu), but is not limited thereto. Alternatively, the first electrode 410 may further include a transparent conductive material layer having a high work function, such as indium tin oxide (ITO).

When the display apparatus 100 is a bottom emission type, the first electrode 410 may be disposed using a transparent conductive material through which light passes. For example, the first electrode 410 may be formed of at least one of indium tin oxide (ITO) and indium zinc oxide (IZO).

The bank 420 may be disposed on the first electrode 410 and the planarization layer 170.

The bank 420 may divide the plurality of sub pixels SP1, SP2, and SP3, minimizes the glaring phenomenon, and may suppress color mixture generated at various viewing angles.

The bank 420 may define (or divide) an emitting unit in which light is emitted and a non-emitting unit in which light is not emitted and may be disposed in the non-emitting unit.

The bank 420 may have a bank hole which exposes the emitting unit and the first electrode 410.

The bank 420 may be formed of at least one or more materials among inorganic insulating materials, such as silicon nitride (SiNx) or silicon oxide (SiOx), organic insulating materials, such as benzocyclobutene (BCB), acrylic resin, epoxy resin, phenolic resin, polyamide resin, or polyimide resin, or photosensitizers including a black pigment, but is not limited thereto.

The bank 420 may be formed to be transparent or black or colored. The bank 420 is configured as a plurality of layers and in this case, may have a structure in which a transparent material and a material configured to be black or colored are laminated.

The bank 420 may be disposed to cover an end of the first electrode 410.

Further, the bank 420 may be disposed on the planarization layer 170 in the non-active area NA. For example, the bank 420 may be disposed so as to cover the planarization layer 170 in the non-active area NA.

The bank 420 of the first area P1 may be disposed to extend from the bank 420 disposed in the active area AA.

At least one spacer 430 may be disposed on the bank 420.

The spacer 430 blocks the damage of the light emitting element layer 440 during the process of the light emitting element layer 440 and may minimize the breakage of the display apparatus 100 caused by the external shocks.

The spacer 430 may be formed of the same material as the bank 420 and may be formed simultaneously with the bank 420, or may be formed by a separate process.

A height of the spacer 430 is larger than a thickness of the bank 420 and a thickness of the spacer 430 may be 1 μm to 2 μm.

The light emitting element layer 440 may be disposed on the first electrode 410 and the bank 420. The light emitting element layer 440 may include an emitting layer EML for emitting light with a specific color in each of the plurality of sub pixels SP1, SP2, and SP3. The emitting layer may be a layer in which light is emitted. For example, holes generated in the first electrode 410 and electrons generated in the second electrode 450 may be injected into the emitting layer. Holes and electrons injected into the emitting layer are coupled to generate excitons. When the generated exciton falls from an excited state to a ground state, light may be generated.

For example, the emitting layer may include one of a red light emitting layer which emits red light, a green light emitting layer which emits green light, a blue light emitting layer which emits blue light, and a white light emitting layer. When the light emitting element layer 440 includes the white light emitting layer, a color filter for converting white light from the white light emitting layer into another color light may be disposed above the light emitting element layer 440. Further, the light emitting element layer 440 may further include a hole injection layer (HIL), a hole transport layer (HTL), an electron blocking layer (EBL), a hole blocking layer (HBL), an electron transport layer (ETL), an electron injection layer (EIL), and the like, but is not limited thereto.

The emitting layer of the light emitting element layer 440 may be disposed in each of the plurality of sub pixels SP1, SP2, and SP3. The hole injection layer (HIL), the hole transport layer (HTL), the electron blocking layer (EBL), the hole blocking layer (HBL), the electron transport layer (ETL), and the electron injection layer (EIL) of the light emitting element layer 440 may be disposed in the entire active area AA.

The light emitting element layer 440 of the display apparatus 100 according to the present disclosure may be an emitting unit. At least one or more emitting units may be disposed. For example, the plurality of emitting units is laminated between the first electrode 410 and the second electrode 450 to configure a stack structure. In this case, a charge generating layer may be further disposed between the plurality of emitting units. A plurality of emitting units may be disposed in each sub pixel SP.

The second electrode 450 may be disposed on the light emitting element layer 440. The second electrode 450 may be a cathode electrode. The second electrode 450 supplies electrons to the light emitting element layer 440 and may be formed of a conductive material having a low work function.

When the display apparatus 100 is a top emission type, the second electrode 450 may be disposed using a transparent conductive material through which light passes. For example, the second electrode may be formed of at least one of indium tin oxide (ITO) and indium zinc oxide (IZO), but is not limited thereto.

Further, the second electrode may be disposed using a translucent conductive material through which light passes. For example, the second electrode may be formed of at least one of alloys such as LiF/Al, CsF/Al, Mg:Ag, Ca/Ag, Ca:Ag, LiF/Mg:Ag, LiF/Ca/Ag, and LiF/Ca:Ag, but is not limited thereto.

When the display apparatus 100 is a bottom emission type, the second electrode 450 may be disposed using an opaque conductive material as a reflective electrode which reflects light. For example, the second electrode 450 may be formed of at least one or more of silver (Ag), aluminum (Al), gold (Au), molybdenum (Mo), tungsten (W), chrome (Cr), or an alloy thereof.

An encapsulation unit 500 may be disposed on the second electrode 450. The encapsulation unit 500 may protect the light emitting element layer 440 from moisture, oxygen, or foreign materials of the outside. For example, the permeation of the oxygen and moisture from the outside may be suppressed to avoid oxidation of an emitting material and an electrode material.

The encapsulation unit 500 may be formed of a transparent material to transmit light emitted from the emitting layer.

The encapsulation unit 500 may include a first encapsulation layer 510, a second encapsulation layer 520, and a third encapsulation layer 530 which block the permeation of moisture or oxygen. The first encapsulation layer 510, the second encapsulation layer 520, and the third encapsulation layer 530 may be alternately laminated.

The first encapsulation layer 510 and the third encapsulation layer 530 may be formed of at least one inorganic material, among silicon nitride (SiNx), silicon oxide (SiOx), or silicon aluminum (AlyOz), but is not limited thereto. The first encapsulation layer 510 and the third encapsulation layer 530 may be formed using a vacuum film forming method such as chemical vapor deposition (CVD) or atomic layer deposition (ALD), but are not limited thereto.

The first encapsulation layer 510 and the third encapsulation layer 530 may be formed as at least two or more layers. For example, the first encapsulation layer 510 may be formed with a triple layered structure of silicon oxide (SiOx)/silicon nitride (SiNx)/silicon oxide (SiOx), but is not limited thereto. Further, the first encapsulation layer 510 is formed with a quadruple layered structure of silicon oxide (SiOx)/silicon nitride (SiNx)/silicon oxide (SiOx)/silicon oxide (SiOx), but is not limited thereto.

The second encapsulation layer 520 may cover foreign materials or particles which may be generated during a manufacturing process. Further, the second encapsulation layer 520 may planarize a surface of the first encapsulation layer 510. For example, the second encapsulation layer 520 may be a particle cover layer, but is not limited to the term.

The second encapsulation layer 520 may be an organic material, for example, a polymer such as silicon oxy carbon (SiOCz), epoxy, polyimide, polyethylene, or acrylate, but is not limited thereto.

The second encapsulation layer 520 may be formed of a thermosetting material or a photo curable material which is cured by heat or light.

The first encapsulation layer 510 may extend to the non-active area NA. For example, the first encapsulation layer 510 may be disposed so as to cover the dam 900. The third encapsulation layer 530 may extend to the non-active area NA. For example, the third encapsulation layer 530 may be disposed on the first encapsulation layer 510 so as to cover the dam 900.

A touch unit 600 may be disposed on the encapsulation unit 500.

The touch unit 600 may include a first touch electrode 640_R, a first touch connection electrode 620, a second touch electrode, and a second touch connection electrode 640_C.

A part of the first touch electrode 640_R, the first touch connection electrode 620, the second touch electrode, and the second touch connection electrode 640_C may be disposed so as to overlap the bank 420.

The first touch electrode 640_R, the second touch electrode, the first touch connection electrode 620, and the second touch connection electrode 620_C may be formed with a mesh pattern in which metal lines having a small line width intersect each other. The mesh pattern may have a rhombus shape and a shape of the mesh pattern may be a rectangle, a pentagon, a hexagon shape, a circle, an oval, or the like, but is not limited thereto.

The first touch electrode 640_R, the second touch electrode, the first touch connection electrode 620, and the second touch connection electrode 640_C may be disposed using an opaque conductive material having a low resistance. For example, the first touch electrode 640_R, the second touch electrode, the first touch connection electrode 620, and the second touch connection electrode 640_C may be formed as a single layer or a plurality of layers formed of any one of molybdenum (Mo), copper (Cu), titanium (Ti), aluminum (Al), chrome (Cr), gold (Au), nickel (Ni), neodymium (Nd), tungsten (W), gold (Au), and transparent conductive oxide (TCO), or an alloy thereof, but are not limited thereto.

For example, the first touch electrode 640_R, the second touch electrode, the first touch connection electrode 620, and the second touch connection electrode 640_C may be configured with a triple structure of titanium (Ti)/aluminum (Al)/titanium (Ti) formed of conductive metal materials, but are not limited thereto.

The first touch electrode 640_R, the second touch electrode, the first touch connection electrode 620, and the second touch connection electrode 640_C may be formed of the same material as the source electrode 250 and the drain electrode 270.

A touch buffer layer 610 may be disposed on the encapsulation layer 500. The touch buffer layer 610 may block a liquid chemical (developer, etchant, or the like) used during the process of manufacturing a touch unit 600 or moisture from the outside from permeating into the light emitting element layer 440 including an organic material. Further, the touch buffer layer 610 may suppress the short-circuit of a plurality of touch sensor metals disposed above the touch buffer layer 610 due to the external shock and block an interference signal which may be generated while driving the touch unit.

The touch buffer layer 610 may be formed of at least one or more materials among inorganic insulating materials, such as silicon nitride (SiNx) or silicon oxide (SiOx) and organic insulating materials, such as benzocyclobutene (BCB), acrylic resin, epoxy resin, phenolic resin, polyamide resin, or polyimide resin. The touch buffer layer 610 may be configured as a plurality of layers, but is not limited thereto.

The first touch connection electrode 620 may be disposed on the touch buffer layer 610.

For example, a first touch connection electrode 620 may be disposed between the first touch electrodes 640_R adjacent in the first direction (or the X-axis direction). The first touch connection electrode 620 may electrically connect the plurality of first touch electrodes 640_R which is spaced apart in the first direction (or the X-axis direction) to be adjacent, but is not limited thereto.

The first touch connection electrode 620 may be disposed so as to overlap the second touch connection electrode 640_C which connects the second touch electrodes adjacent in the second direction (or the Y-axis direction). The first touch connection electrode 620 and the second touch connection electrode 640_C are formed on different layers to be electrically insulated.

A touch insulating layer 630 may be disposed on the touch buffer layer 610 and the first touch connection electrode 620.

The touch insulating layer 630 may include a hole to electrically connect the first touch electrode 640_R and the first touch connection electrode 620.

The touch insulating layer 630 may electrically insulate the second touch electrode and the second touch connection electrode 640_C.

The touch insulating layer 630 may be formed as a single layer of silicon nitride (SiNx) or silicon oxide (SiOx) or a multilayer thereof, but is not limited thereto.

The first touch electrode 640_R, the second touch electrode, and the second touch connection electrode 640_C may be disposed on the touch insulating layer 630.

The first touch electrode 640_R and the second touch electrode may be disposed to be spaced apart from each other with a predetermined interval. At least one or more first touch electrodes 640_R adjacent in the first direction (or the X-axis direction) may be formed to be spaced apart from each other. At least one or more first touch electrodes 640_R adjacent to each other in the first direction (or the X-axis direction) may be connected to the first touch connection electrode 620 disposed between the plurality of first touch electrodes 740_R. For example, the plurality of adjacent first touch electrodes 640_R may be connected to the first touch connection electrode 620 by means of the hole of the touch insulating layer 630.

The second touch electrode adjacent in the second direction (or the Y-axis direction) may be connected by the second touch connection electrode 640_C. The second touch electrode and the second touch connection electrode 640_C may be formed on the same layer. For example, the second touch connection electrode 640_C may be disposed between the plurality of second touch electrodes on the same layer as the second touch electrode. The second touch connection electrode 640_C extends from the second touch electrode.

The first touch electrode 640_R, the second touch electrode, and the second touch connection electrode 640_C may be formed by the same process.

A touch planarization layer 650 may be disposed on the first touch electrode 640_R, the second touch electrode, and the second touch connection electrode 640_C.

The touch driving circuit may receive a touch sensing signal from the first touch electrode 640_R. Further, the touch driving circuit may transmit a touch driving signal from the second touch electrode. The touch driving circuit senses the user's touch using mutual capacitance between the plurality of first touch electrodes 640_R and the second touch electrode. For example, when the touch operation is performed on the display apparatus 100, a capacitance between the first touch electrode 640_R and the second touch electrode may be changed. The touch driving circuit may sense the capacitance change to detect a touch coordinate.

Referring to FIG. 5, to be more specific, the non-active area NA is an area adjacent to the active area AA and may include a first area P1, a second area P2, and a third area P3.

The first area P1 is an area adjacent to the active area AA and in the first area P1, the planarization layer 170 may be disposed. The planarization layer 170 of the first area P1 may be disposed by extending the planarization layer 170 disposed in the active area AA to the non-active area NA. The first area P1 may further include a bank 420 and/or an encapsulation unit 500 on the planarization layer 170.

The second area P2 is an area adjacent to the first area P1 and is formed by etching the planarization layer 170 to be removed.

The planarization layer 170 may be disposed in the first area P1 of the non-active area NA and an end point of the planarization layer 170 may divide the first area P1 and the second area P2. For example, the first area P1 may be an area from an end point of the active area AA to an end point of the planarization layer 170 and the second area P2 may be an area in which the planarization layer 170 is not disposed.

The third area P3 is an area adjacent to the second area P2 in the non-active area NA and may be disposed to enclose the second area P2. The third area P3 may be an area in which the planarization layer 170 is disposed in the non-active area NA. The third area P3 is adjacent to the bending area BA and a connection line extending from the bending area BA may be disposed therein.

The second area P2 may be disposed between the first area P1 and the third area P3. For example, the second area P2 may be an area which is disposed between one end of the planarization layer 170 disposed in the first area P1 and one end of the planarization layer 170 disposed in the third area P3.

At this time, when a location S where angles of the first signal line 710 or the second signal line 720 are changed overlaps the third area P3, a curve may be generated in the first power line VDD disposed above the first signal line 710 or the second signal line 720 due to a step of the first signal line 710 or the second signal line 720. In this case, the planarization layer 170 is disposed in the third area P3 so that moisture or oxygen of the planarization layer 170 of the third area P3 may move to the active area AA through a curve of the first power line VDD. For example, in the first power line VDD, a pore is formed by the curve and the moisture or oxygen of the planarization layer 170 may move through the pore of the first power line VDD. The moisture or oxygen permeates into the active area AA through the first power line VDD to cause a driving defect of the thin film transistor.

Therefore, inventors of the present disclosure invented a display apparatus in which a location S in which an angle of the first signal line 710 or the second signal line 720 was changed was disposed in a second area P2 in which the planarization layer 170 was not disposed to block permeation of moisture or oxygen of the planarization layer 170 disposed in the non-active area NA into the active area AA. Therefore, a stability of the thin film transistor was ensured to improve a display quality.

Referring to FIG. 5, the location S in which an angle of the first signal line 710 or the second signal line 720 is changed may be spaced apart from the third area P3. As described above, the location S in which an angle of the first signal line 710 or the second signal line 720 is changed is spaced apart from the third area P3 so that the first power line VDD disposed above the first signal line 710 or the second signal line 720 is planarized. Therefore, the movement of the moisture or oxygen through the pore caused by the curve of the first power line VDD to the active area AA may be blocked.

The exemplary embodiments of the present disclosure can also be described as follows:

According to an aspect of the present disclosure, there is provided a display apparatus. The display apparatus includes a substrate which is configured by an active area and a non-active area including a first area adjacent to the active area, a second area adjacent to the first area, and a third area adjacent to the second area. The display apparatus further includes a first signal line and a second signal line disposed in the non-active area. The first signal line and the second signal line include a first part and a second part which are disposed to have different angles, respectively, and a location where an angle between the first part and the second part is changed is located in the second area.

The first part may be a part perpendicular to one side of the active area and the second part may have an angle different from that of the first part.

Locations where the angles between the first part and the second part of the first signal line and the second signal line are changed may be spaced apart from the third area.

A planarization layer may be disposed in the first area and the third area, and in the second area, the planarization layer may be not disposed.

The display apparatus may further include a power line which is disposed in the first area, the second area, and the third area, and is disposed on the first signal line and the second signal line.

A portion of the power line disposed in an area where the third area and the second area are adjacent to each other may not have steps.

The display apparatus may further include a dam disposed on the power line in the second area.

The display apparatus may further include a thin film transistor which is disposed in the active area and includes a semiconductor pattern, a gate electrode, a source electrode, and a drain electrode; and a storage capacitor including a first capacitor electrode and a second capacitor electrode.

The first signal line may be disposed on the same layer as the gate electrode and the second signal line may be disposed on the same layer as the second capacitor electrode.

The first signal line may transmit a gate signal and the second signal line may transmit a data signal.

Locations where the angles between the first part and the second part of the first signal line and the second signal line are changed may overlap the power line.

The power line may include a first power line, and the first power line may be disposed between the active area and a bending area.

Locations where the angles between the first part and the second part of the first signal line and the second signal line are changed may be disposed between the active area and the bending area.

The first signal line and the second signal line may be not disposed below the portion of the power line disposed in the area where the third area and the second area are adjacent to each other.

Although the exemplary embodiments of the present disclosure have been described in detail with reference to the accompanying drawings, the present disclosure is not limited thereto and may be embodied in many different forms without departing from the technical concept of the present disclosure. Therefore, the exemplary embodiments of the present disclosure are provided for illustrative purposes only but not intended to limit the technical concept of the present disclosure. The scope of the technical concept of the present disclosure is not limited thereto. Therefore, it should be understood that the above-described exemplary embodiments are illustrative in all aspects and do not limit the present disclosure.

The various embodiments described above can be combined to provide further embodiments. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display apparatus, comprising:
a substrate including an active area and a non-active area, the non-active area including a first area adjacent to the active area, a second area adjacent to the first area, and a third area adjacent to the second area; and
a first signal line and a second signal line disposed in the non-active area,
wherein at least one of the first signal line and the second signal line includes a first part and a second part,
wherein the first part and the second part have different angles relative to the non-active area, respectively, and
wherein an interface between the first part and the second part is located in the second area.

2. The display apparatus according to claim 1, wherein the first part is perpendicular to a side of the active area.

3. The display apparatus according to claim 1, wherein the interface between the first part and the second part is spaced apart from the third area.

4. The display apparatus according to claim 1, further comprising:
a planarization layer disposed in the first area and the third area, wherein the planarization layer is absent from the second area.

5. The display apparatus according to claim 1, further comprising:
a power line disposed in the first area, the second area, and the third area,
wherein the power line is disposed on the first signal line and the second signal line.

6. The display apparatus according to claim 5, wherein a portion of the power line disposed at a boundary between the third area and the second area does not have steps.

7. The display apparatus according to claim 5, further comprising:
a dam disposed on the power line in the second area.

8. The display apparatus according to claim 1, further comprising:
a thin film transistor disposed in the active area, the thin film transistor including a semiconductor pattern, a gate electrode, a source electrode, and a drain electrode; and
a storage capacitor including a first capacitor electrode and a second capacitor electrode.

9. The display apparatus according to claim 8, wherein the first signal line is disposed on a same layer as the gate electrode and the second signal line is disposed on a same layer as the second capacitor electrode.

10. The display apparatus according to claim 1, wherein the first signal line is configured to transmit a gate signal and the second signal line is configured to transmit a data signal.

11. The display apparatus according to claim 5, wherein the interface between the first part and the second part overlaps the power line.

12. The display apparatus according to claim 5, wherein the power line includes a first power line, and
wherein the first power line is disposed between the active area and a bending area of the substrate.

13. The display apparatus according to claim 12, wherein the interface between the first part and the second part is disposed between the active area and the bending area.

14. The display apparatus according to claim 6, wherein the first signal line and the second signal line are not disposed below the portion of the power line at a boundary between the third area and the second area.

15. A display apparatus, comprising:
a substrate including an active area and a non-active area; and
a first signal line and a second signal line disposed in the non-active area,
wherein each of the first signal line and the second signal line include a respective first portion and a respective second portion, and
wherein the first portion and the second portion of each of the first signal line and the second signal line are angled relative to each other.

16. The display apparatus of claim 15, wherein the first portion of each of the first signal line and the second signal line is straight and the second portion of each of the first signal line and the second signal line is angled with respect to the first portion.

17. The display apparatus of claim 15, further comprising:
a power line disposed in the non-active area, wherein an interface between the first portion and the second portion of each of the first signal line and the second signal line overlaps the power line.

18. A display apparatus, comprising:
a substrate including an active area and a non-active area; and
a signal line disposed in the non-active area,
wherein the signal line includes a first portion and a second portion at an angle to the first portion.

19. The display apparatus of claim 18, wherein the first portion is straight.

20. The display apparatus of claim 18, further comprising:
a power line overlapping an interface between the first portion and the second portion of the signal line.
